(19) United States
(12) Patent Application Publication
(10) Pub. No.: US 2015/0289359 A1
(43) Pub. Date: Oct. 8, 2015

(54) Circuit Card Apparatus And Methods

(71) Applicant: DY 4 Systems Inc., Kanata (CA)

(72) Inventors: Bob Schmidt, Nepean (CA); Rick Power-Fardy, Ottawa (CA); Ivan Straznicky, Carleton Place, Ontario (CA)

(73) Assignee: DY 4 Systems Inc., Kanata (CA)

(21) Appl. No.: 14/243,104

(22) Filed: Apr. 2, 2014

(51) Int. Cl. H05K 1/02; H05K 7/20

(52) U.S. Cl. CPC H05K 1/0209; H05K 7/2039; H05K 2201/066

(57) ABSTRACT

A circuit card apparatus includes a circuit card and a heat dissipation device in thermal contact with the circuit card at a thermal interface to conduct heat from the circuit card. An adjustable spacing element is adjustably coupled to one of the heat dissipation device and the circuit card. The adjustable spacing element is configured to be adjusted to set a minimum spaced distance between a portion of the circuit card and a portion of the heat dissipation device. A locking element is coupled to the adjustable spacing element to lock the minimum spaced distance. In further examples, methods of manufacturing a circuit card apparatus include the step of adjusting a spacing element to set the spaced distance as a minimum spaced distance between a portion of a heat dissipation device and a portion of a circuit card. The method further comprises the step of locking the minimum spaced distance.

### FIELD

The present invention relates generally to a circuit card apparatus and methods, and more particularly, to a circuit card apparatus comprising an adjustable spacing element and a locking element and methods including the step of adjusting a spacing element to set a spaced distance as a minimum spaced distance between a portion of a heat dissipation device and a portion of a circuit card.

### BACKGROUND

It is common for features (e.g., electronic components) of a circuit card to heat up when operating a circuit card apparatus including the circuit card. There is a desire to remove heat from the circuit card to control an associated temperature. For example, one or more electronic components of the circuit card may heat up when operating the circuit card apparatus. In such examples, there may be a desire to remove heat from the one or more electronic components to control the temperature to prevent overheating of the electronic components above a desired or maximum operating temperature.

### SUMMARY

The following presents a simplified summary of the disclosure in order to provide a basic understanding of some example aspects described in the detailed description.

In a first aspect, a circuit card apparatus comprises a circuit card and a heat dissipation device in thermal contact with the circuit card at a thermal interface to conduct heat from the circuit card. An adjustable spacing element is adjustably coupled to one of the heat dissipation device and the circuit card. The adjustable spacing element is configured to be adjusted to set a minimum spaced distance between a portion of the circuit card and a portion of the heat dissipation device. A locking element is coupled to the adjustable spacing element to lock the minimum spaced distance.

In one example of the first aspect, the adjustable spacing element comprises a threaded spacing element threadably coupled to the one of the heat dissipation device and the circuit card.

In another example of the first aspect, the adjustable spacing element provides a stop defining the minimum spaced distance with a surface of the adjustable spacing element abutting a first surface of the other of the heat dissipation device and the circuit card. For example, a surface of the locking element can abut a second surface of the other of the heat dissipation device and the circuit card to lock the minimum spaced distance.

In still another example of the first aspect, the adjustable spacing element comprises a threaded bore and the locking element comprises a threaded member threadably inserted into the threaded bore.

In a further example of the first aspect, the locking element comprises a threaded bore and the adjustable spacing element comprises a threaded member threadably inserted into the threaded bore.

In still a further example of the first aspect, the thermal interface includes a reflowed thermal interface material.

The first aspect may be carried out alone or with one or any combination of the examples of the first aspect discussed above.

In a second aspect, a circuit card apparatus comprises a circuit card including a first major surface facing a first direction and a second major surface facing a second direction opposite the first direction. A heat dissipation device is in thermal contact with the circuit card at a thermal interface to conduct heat from the circuit card. A threaded spacing element is threadedly coupled to a threaded bore of the heat dissipation device to set a minimum spaced distance between a portion of the circuit card and a portion of the heat dissipation device, wherein the threaded spacing element provides a stop defining the minimum spaced distance with a surface of the threaded spacing element abutting the first major surface of the circuit card. A locking element is threadedly coupled to the threaded spacing element, wherein a surface of the locking element abuts the second major surface of the circuit card to lock the minimum spaced distance.

In one example of the second aspect, the threaded spacing element comprises a threaded bore and the locking element comprises a threaded member threadably inserted into the threaded bore.

In another example of the second aspect, the locking element comprises a threaded bore and the threaded spacing element comprises a threaded member threadably inserted into the threaded bore.

In still another example of the second aspect, the thermal interface includes a reflowed thermal interface material.

The second aspect may be carried out alone or with one or any combination of the examples of the second aspect discussed above.

In a third aspect, a method of manufacturing a circuit card apparatus comprises the step (I) of pressing a thermal contact surface of a heat dissipation device against a thermal contact surface of a circuit card at a thermal interface, wherein a spaced distance is defined between a portion of the heat dissipation device and a portion of the circuit card. The method further comprises the step (II) of adjusting a spacing element to set the spaced distance as a minimum spaced distance between the portion of the heat dissipation device and the portion of the circuit card. The method further comprises the step (III) of locking the minimum spaced distance.

In one example of the third aspect, step (I) includes melting a thermal interface material at the thermal interface to thermally couple the thermal contact surface of the heat dissipation device with the thermal contact surface of the circuit card. For example, the method can further comprise the step of solidifying the melted interface material prior to step (II).

In another example of the third aspect, step (III) includes threadably coupling a locking element to the spacing element.

In still another example of the third aspect, step (I) provides the thermal interface with a pressure that is within a range of from about 34.5 kPa (5 psi) to about 416.7 kPa (60 psi).

In yet another example of the third aspect, step (II) includes adjusting the spacing element until a surface of the spacing element abuts a first surface of one of the circuit card and the heat dissipation device to provide a stop defining the minimum spaced distance.

In a further example of the third aspect, step (II) includes threading the spacing element through a threaded bore of one of the circuit card and the heat dissipation device. For example, step (II) can include adjusting the spacing element until a surface of the spacing element abuts a first surface of the other of the circuit card and the heat dissipation device to provide a stop defining the minimum spaced distance.

In still a further example of the third aspect, step (II) includes threadably adjusting the spacing element through a threaded bore of the heat dissipation device until a surface of the spacing element abuts a first surface of the circuit card to provide a stop defining the minimum spaced distance, and step (III) includes threadably coupling a locking element to the spacing element such that a surface of the locking element abuts a second surface of the circuit card.

The third aspect may be carried out alone or with one or any combination of the examples of the third aspect discussed above.

### BRIEF DESCRIPTION OF THE DRAWINGS

These and other features, aspects and advantages of the present disclosure are better understood when the following detailed description is read with reference to the accompanying drawings, in which:

FIG. 1 is a side view of an example circuit card apparatus;

FIG. 2 is a partial, cross-sectional view of the example circuit card apparatus comprising a spacing element and a locking element of a first embodiment;

FIG. 3 is a partial, cross-sectional view of the example circuit card apparatus comprising a spacing element and a locking element of a second embodiment;

FIG. 4 is a partial, cross-sectional view of the example circuit card apparatus comprising a spacing element and a locking element of a third embodiment;

FIG. 5 is a partial, cross-sectional view of the example circuit card apparatus comprising a spacing element and a locking element of a fourth embodiment;

FIG. 6 illustrates one step of an example method of manufacturing the example circuit card apparatus;

FIG. 7 illustrates a second step of the example method;

FIG. 8 illustrates a third step of the example method;

FIG. 9 illustrates a fourth step of the example method;

FIG. 10 illustrates a fifth step of the example method; and

FIG. 11 illustrates a sixth step of the example method.

### DETAILED DESCRIPTION

Apparatus and methods will now be described more fully hereinafter with reference to the accompanying drawings in which example embodiments of the disclosure are shown. Whenever possible, the same or similar reference numerals are used throughout the drawings to refer to the same or like parts. However, this disclosure may be embodied in many different forms and should not be construed as limited to the embodiments set forth herein.

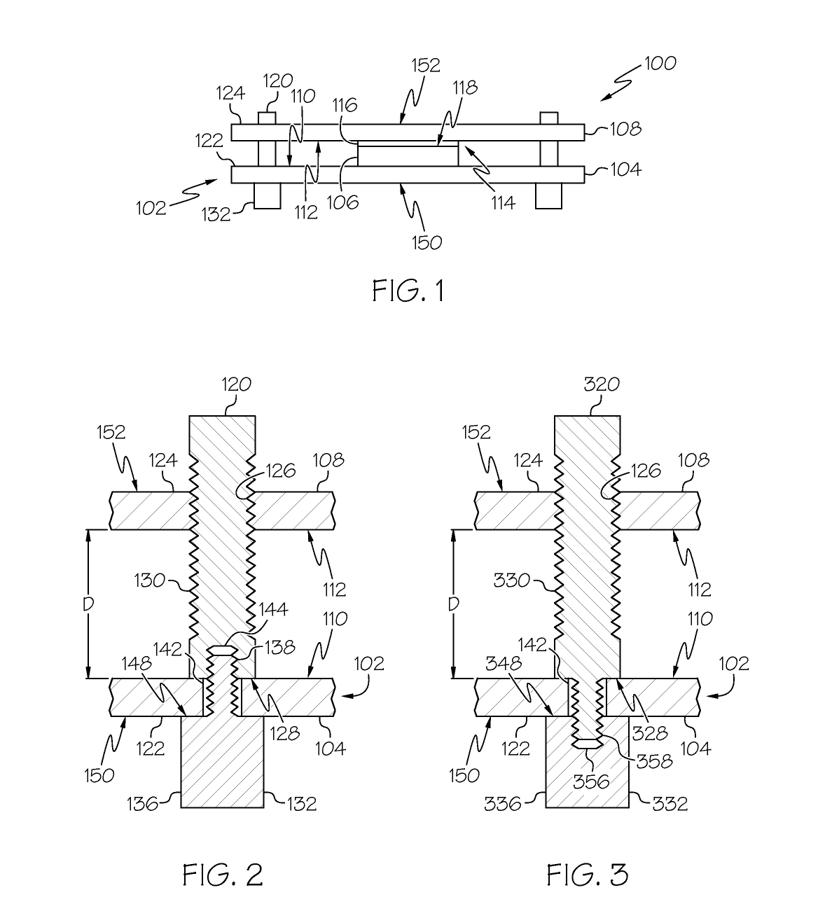

Turning to FIG. 1, an example circuit card apparatus 100 is illustrated that comprises a circuit card 102 having a circuit board 104 and a heat generating component 106 attached to the circuit board 104. The heat generating component 106 may be a semiconductor die or other integrated circuit device. Additionally, the heat generating component 106 may rest upon and be coupled to a separate component that is coupled to the circuit board 104, thus providing an attachment between the heat generating component 106 and the circuit board 104. Moreover, the circuit card 102 may comprise a plurality of components including for example other heat generating components that are attached to the circuit board 104.

A heat dissipation device 108 is provided that is configured to transfer heat away from the heat generating component 106. The heat dissipation device 108 may be a conduction cooling device that makes use of a metal thermal frame that transfers heat from the heat generating component 106 to a chassis wall. Alternatively, the heat dissipation device 108 may comprise one or more heat pipe evaporator elements containing a wick structure and working fluid that uses latent heat of vaporization to move heat from one area of the pipe to another. The heat dissipation device 108 can be any device configured to remove heat from the heat generating component 106.

The heat dissipation device 108 is arranged such that a surface 110 of the circuit board 104 faces a thermal contact surface 112 of the heat dissipation device 108. Additionally, the heat dissipation device 108 is in thermal contact with the circuit card 102 at a thermal interface 114 to conduct heat from the circuit card 102. The thermal interface 114 includes a thermal interface material 116 that is provided between the thermal contact surface 112 of the heat dissipation device 108 and a thermal contact surface 118 of the heat generating component 106 and permits heat to transfer between the heat generating component 106 and the heat dissipation device 108. The thermal interface material 116 may consist of a variety of materials, for example a phase change material or a metal solder material.

An adjustable spacing element is adjustably coupled to one of the heat dissipation device 108 and the circuit card 102 and is configured to be adjusted to set a minimum spaced distance D between a portion 122 of the circuit card 102 and a portion 124 of the heat dissipation device 108. Moreover, a locking element can be coupled to the adjustable spacing element to lock the minimum spaced distance D. For example, as shown in FIGS. 1 & 2, an adjustable spacing element 120 is provided that comprises a threaded spacing element and can be threadably coupled to the heat dissipation device 108 by threading an externally threaded spacing element 120 through an internally threaded bore 126 of the heat dissipation device. The adjustable spacing element 120 provides a stop portion 130 that can protrude from the surface 112 of the heat dissipation device 108 when the adjustable spacing element 120 is coupled to the heat dissipation device 108. The heat dissipation device 108 and the spacing element 120 coupled thereto can be aligned such that a surface 128 of the spacing element 120 faces and abuts the surface 110 of the circuit board 104. The portion 124 of the heat dissipation device 108 will thus be spaced from the portion 122 of the circuit card 102 a distance equivalent to the length of the stop portion 130 that protrudes from the surface 112. Moreover, the stop portion 130 will prohibit the heat dissipation device 108 from being positioned such that the portion 124 is spaced a distance from the portion 122 that is less than the length of the stop portion 130 that protrudes from the surface 112. Since the spacing element 120 is adjustably coupled to the heat dissipation device 108, the length of the stop portion 130 that protrudes from the surface 112 can be adjusted to set the minimum spaced distance D. In this way, the stop portion 130 defines the minimum spaced distance D.

A locking element 132 can be coupled to the adjustable spacing element 120 to lock the minimum spaced distance D. The locking element 132 includes a base portion 136 and a threaded member 138 that extends from the base portion 136. The locking element 132 can be coupled to the spacing element 120 such that the externally threaded member 138 extends through a bore 142 in the circuit board 104 and is threadably inserted into an internally threaded bore 144 in the spacing element 120. When coupled to the spacing element 120, a surface 148 of the locking element 132 can abut a surface 150 of the circuit board 104, thus preventing the surface 128 of the coupled spacing element 120 from losing contact with the surface 110 of the circuit board 104. As such, the locking element 132 locks the minimum spaced distance D by preventing relative movement of the portion 124 of the heat dissipation device 108 and the portion 122 of the circuit card 102.

Although the spacing element 120 and the locking element 132 described above may be used to space and lock in position the portion 124 of the heat dissipation device 108 relative to the portion 122 of the circuit card 102, the spacing element 120 and the locking element 132 may be used to space and lock other portions of the heat dissipation device 108 and the circuit card 102. Moreover, the apparatus 100 may comprise more than one spacing element 120 and more than one locking element 132 to space and lock multiple portions of the heat dissipation device 108 and the circuit card 102. Furthermore, the apparatus 100 may comprise spacing and locking elements that vary in configuration from the spacing element 120 and the locking element 132 described above. For example, turning to FIG. 3, an embodiment is illustrated wherein an adjustable spacing element 320 is adjustably coupled to the heat dissipation device 108 and is configured to be adjusted to set the minimum spaced distance D. The adjustable spacing element 320 can be threadably coupled to the heat dissipation device 108 such that a stop portion 330 of the spacing element 320 protrudes from the surface 112 of the heat dissipation device 108. The heat dissipation device 108 and the spacing element 320 coupled thereto can similarly be aligned such that a surface 328 of the spacing element 120 faces and abuts the surface 110 of the circuit board 104, thus spacing the portion 124 of the heat dissipation device 108 from the portion 122 of the circuit card 102 a distance equivalent to the length of the stop portion 330 that protrudes from the surface 112.

A locking element 332 can be coupled to the adjustable spacing element 320 to lock the minimum spaced distance D. The locking element 332 in the present embodiment includes a base portion 336 and an internally threaded bore 356 configured to receive an externally threaded member 358 of the spacing element 320. The spacing element 320 can be coupled to the locking element 332 such that the externally threaded member 358 extends through the bore 142 in the circuit board 104 and is threadably inserted into the internally threaded bore 356 in the locking element 332. When coupled to the spacing element 320, a surface 348 of the locking element 332 can abut the surface 150 of the circuit board 104, thus preventing the surface 328 of the coupled spacing element 320 from losing contact with the surface 110 of the circuit board 104. As such, the locking element locks the minimum spaced distance D such that the portion 124 of the heat dissipation device 108 will be locked in position relative to the portion 122 of the circuit card 102 and will remain spaced from the portion 122 the minimum spaced distance D.

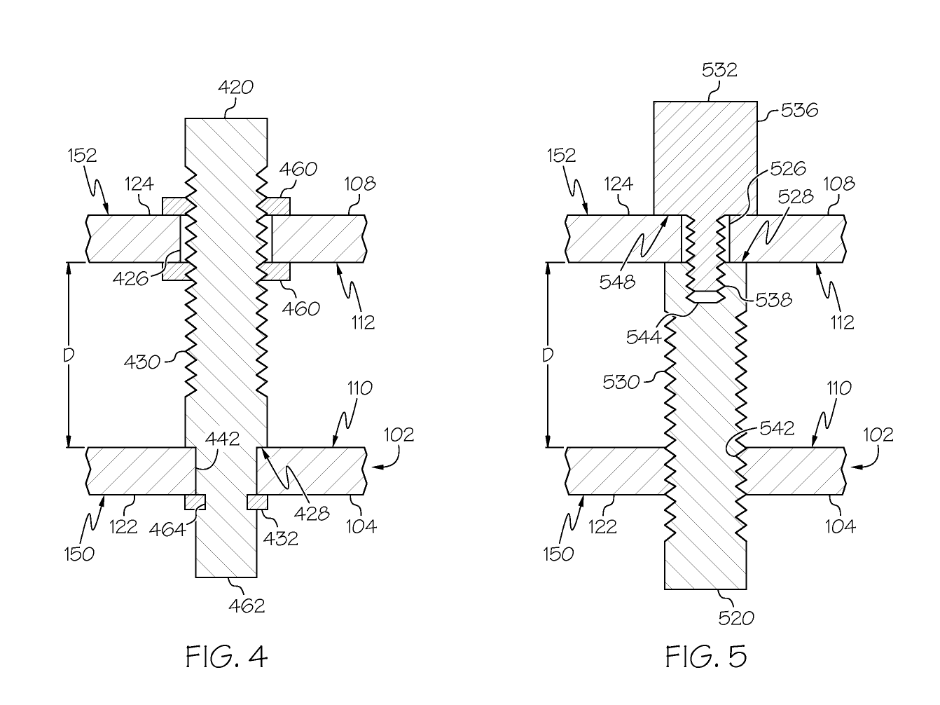

As shown in FIG. 4, an adjustable spacing element 420 can also be adjustably coupled to the heat dissipation device 108 by inserting the spacing element 420 through a bore 426 in the heat dissipation device 108 and providing threaded fasteners 460 along the spacing element 420 on one or opposite sides 112, 152 of the heat dissipation device 108. The adjustable spacing element 420 can be thereby indirectly threadably coupled to the heat dissipation device 108 such that a stop portion 430 of the spacing element 420 protrudes from the surface 112 of the heat dissipation device 108. A surface 428 of the stop portion 430 can engage the surface 110 of the circuit board to define the minimum spaced distance D.

Moreover, the adjustable spacing element 420 can comprise a member 462 that extends through a bore 442 in the circuit board 104 and comprises an annular groove 464 for receiving a locking element 432. The locking element 432 may comprise a snap ring that will rest within the annular groove 464 and abut the surface 150 of the circuit board 104, thus preventing a surface 428 of the spacing element 420 from losing contact with the surface 110 of the circuit board 104. As such, the locking element 432 can be coupled to the adjustable spacing element 420 to lock the minimum spaced distance D.

In yet other embodiments, the apparatus 100 may include a locking element that comprises a cotter pin, a nut, or some other fastener which can be coupled to a spacing element to lock the minimum spaced distance D. Moreover, there may be embodiments wherein a spacing element is adjustably coupled to the circuit card 102 rather than the heat dissipation device 108. For example, as shown in FIG. 5, an adjustable spacing element 520 can be threadably coupled to the circuit card 102 by threading the externally threaded spacing element 520 through an internally threaded bore 542 of the circuit board 104. The adjustable spacing element 520 can be threadably coupled to the circuit card 102 at a desired adjusted position such that a stop portion 530 of the spacing element 520 protrudes from the surface 110 of the circuit board 104 and a surface 528 of the spacing element 520 faces and abuts the surface 112 of the heat dissipation device 108. Thus, the minimum spaced distance D is defined between the portion 124 of the heat dissipation device 108 and the portion 122 of the circuit card 102 that is equivalent to the length of the stop portion 530 that protrudes from the surface 110.

A locking element 532 can be coupled to the adjustable spacing element 520 to lock the minimum spaced distance D. The locking element 132 includes a base portion 536 and an externally threaded member 538 that extends from the base portion 536. The locking element 532 can be coupled to the spacing element 520 such that the threaded member 538 extends through bore 526 in the heat dissipation device 108 and is threadably inserted into an internally threaded bore 544 in the spacing element 520. When coupled to the spacing element 520, a surface 548 of the locking element 532 can abut the surface 152 of the heat dissipation device 108, thus preventing the surface 528 of the coupled spacing element 520 from losing contact with the surface 112 of the heat dissipation device 108. As such, the portion 124 of the heat dissipation device 108 will be locked in position relative to the portion 122 of the circuit card 102 and will remain spaced from the portion 122 the minimum spaced distance D.

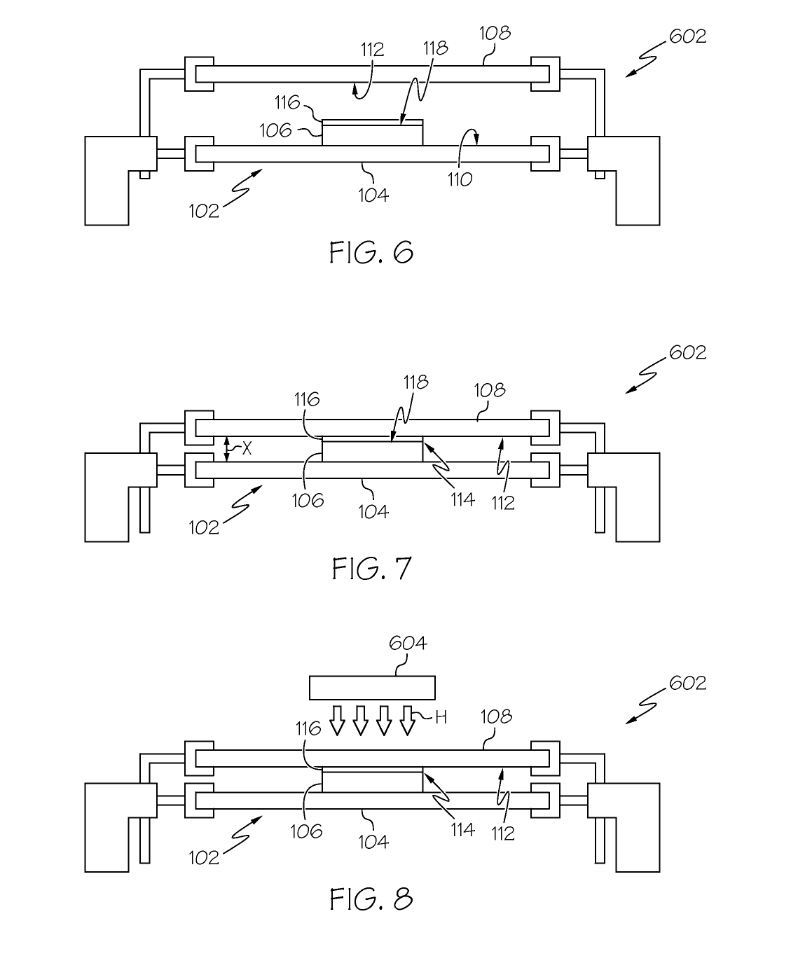

Turning to FIGS. 6-11, an example method will now be described of manufacturing the circuit card apparatus 100 utilizing the spacing element 120 and the locking element 132 described above. However, it should be appreciated that spacing and locking elements having different configurations may be similarly utilized with the method, for example the spacing elements 320, 420, 520 and the locking elements 332, 432, 532.

The method comprises the step of providing the circuit card 102 and the heat dissipation device 108. As shown in FIG. 6, the circuit card 102 and the heat dissipation device 108 may be placed in an assembly fixture 602 that is configured to control the positioning of the circuit card 102 and the heat dissipation device 108. The heat dissipation device 108 and the circuit card 102 are arranged such that the surface 110 of the circuit board 104 faces the thermal contact surface 112 of the heat dissipation device 108. Additionally, the thermal interface material 116 may be applied to the thermal contact surface 118 of the heat generating component 106 of the circuit card 102.

The method further comprises the step of pressing the thermal contact surface 112 of the heat dissipation device 108 against the thermal contact surface 118 of the circuit card 102 at the thermal interface 114. For example, as shown in FIG. 7, the assembly fixture 602 can provide relative movement between the circuit board 104 and the heat dissipation device 108, for example by lowering the heat dissipation device 108, to press the thermal contact surface 112 against the thermal contact surface 118 and apply pressure to the thermal interface 114. Pressing the thermal contact surfaces 112, 118 together can aid in spreading the thermal interface material 116 across the thermal contact surfaces 112, 118; thereby providing a proper thermal connection between the heat dissipation device 108 and the circuit card 102. A spaced distance X is consequently defined between the portion 124 of the heat dissipation device 108 and the portion 122 of the circuit card 102. In some examples, the pressing the thermal contact surfaces 112, 118 together can provide the thermal interface with a pressure that is within a range of from about 34.5 kPa (5 psi) to about 416.7 kPa (60 psi). However, the interface pressure can fall within other ranges depending on the type of thermal interface material being used and the fragility of the heat generating component 106 or circuit board 104. If provided, the applied pressure can be at least be sufficient to provide a proper thermal connection between the heat dissipation device 108 and the circuit card 102 but can also avoid exceeding a value that imparts a load on the heat generating component 106 that is greater than the component's maximum withstandable load.

The method further comprises the step of melting the thermal interface material 116 at the thermal interface 114 to thermally couple the thermal contact surface 112 of the heat dissipation device 108 with the thermal contact surface 118 of the circuit card 102. As shown in FIG. 8, a heating fixture 604 may be used to apply heat H to the thermal interface material 116 to melt and achieve reflow of the thermal interface material 116 across the thermal contact surface 118. The heating fixture 604 may comprise heating coils, an infrared lamp, or some other device configured to provide heat to the thermal interface material 116. Once heated, the thermal interface material 116 may be cooled to then solidify the melted interface material. The solidified melted interface material can provide enhanced thermal coupling between the thermal contact surfaces.

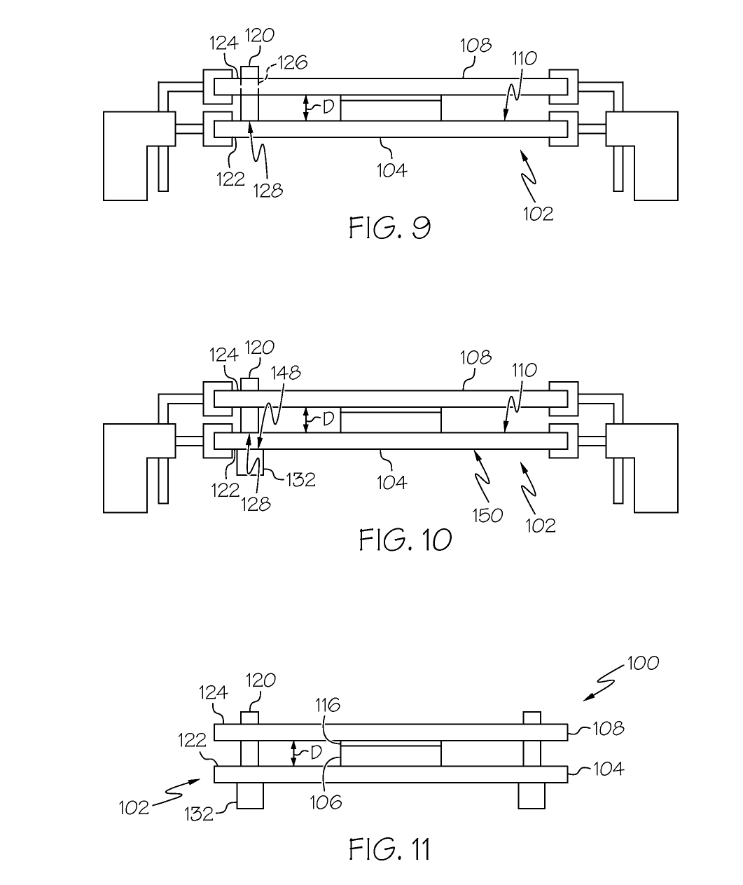

The method additionally comprises the step of adjusting the spacing element 120 to set the spaced distance X as the minimum spaced distance D between the portion 124 of the heat dissipation device 108 and the portion 122 of the circuit card 102, as shown in FIG. 9. The step can include threading the externally threaded spacing element 120 through the internally threaded bore 126 of the heat dissipation device 108. Once threadably coupled, the spacing element 120 may be adjusted until the surface 128 of the spacing element 120 abuts the surface 110 of the circuit card 102 to provide a stop defining the minimum spaced distance D. Over adjustment of the spacing element 120 may result in a jacking of the heat dissipation device 108 relative to the circuit card 102, thus setting the minimum spaced distance D to be greater than the spaced distance X. To avoid such over adjustment, the torque applied to the spacing element 120 during adjustment may be controlled to avoid exceeding a maximum torque value. For instance, in one example, the torque applied to the spacing element 120 can be controlled not to exceed 0.7 N·cm (0.5 inch-oz).

The method further includes the step of locking the minimum spaced distance D. As shown in FIG. 10, the step of locking the minimum spaced distance D can include threadably coupling the locking element 132 to the spacing element 120 such that the surface 148 of the locking element 132 abuts the surface 150 of the circuit card 102. Once coupled to the locking element 132, the surface 128 of the spacing element 120 will be prevented from losing contact with the surface 110 of the circuit board 104.

Other portions of the heat dissipation device 108 and the circuit card 102 may be similarly spaced and locked using similar or like spacing and locking elements. Moreover, once the spacing elements and locking elements are coupled, the circuit card apparatus 100 may be removed from the assembly fixture 602, as shown in FIG. 11.

In other embodiments of the method described above, rather than threading the spacing element 120 through the threaded bore 126 of the heat dissipation device 108, the externally threaded spacing element 520 may be threaded through the internally threaded bore 542 of the circuit card 102 as shown in FIG. 5. The spacing element 520 may then be adjusted until the surface 528 of the spacing element 520 abuts the surface 112 of the heat dissipation device 108. The locking element 532 may then be threadably coupled to the spacing element 520 such that the surface 548 abuts the surface 152 of the heat dissipation device 108.

It will be apparent to those skilled in the art that various modifications and variations can be made to the present disclosure without departing from the spirit and scope of the invention. Thus, it is intended that the present invention cover the modifications and variations of this disclosure provided they come within the scope of the appended claims and their equivalents.

What is claimed is:

1. A circuit card apparatus comprising:
a circuit card;
a heat dissipation device in thermal contact with the circuit card at a thermal interface to conduct heat from the circuit card;
an adjustable spacing element adjustably coupled to one of the heat dissipation device and the circuit card, wherein the adjustable spacing element is configured to be adjusted to set a minimum spaced distance between a portion of the circuit card and a portion of the heat dissipation device; and
a locking element coupled to the adjustable spacing element to lock the minimum spaced distance.

2. The circuit card apparatus of claim 1, wherein the adjustable spacing element comprises a threaded spacing element threadably coupled to the one of the heat dissipation device and the circuit card.

3. The circuit card apparatus of claim 1, wherein the adjustable spacing element provides a stop defining the minimum spaced distance with a surface of the adjustable spacing element abutting a first surface of the other of the heat dissipation device and the circuit card.

4. The circuit card apparatus of claim 3, wherein a surface of the locking element abuts a second surface of the other of the heat dissipation device and the circuit card to lock the minimum spaced distance.

5. The circuit card apparatus of claim 1, wherein the adjustable spacing element comprises a threaded bore and the locking element comprises a threaded member threadably inserted into the threaded bore.

6. The circuit card apparatus of claim 1, wherein the locking element comprises a threaded bore and the adjustable spacing element comprises a threaded member threadably inserted into the threaded bore.

7. The circuit card apparatus of claim 1, wherein the thermal interface includes a reflowed thermal interface material.

8. A circuit card apparatus comprising:
a circuit card including a first major surface facing a first direction and a second major surface facing a second direction opposite the first direction;
a heat dissipation device in thermal contact with the circuit card at a thermal interface to conduct heat from the circuit card;
a threaded spacing element threadedly coupled to a threaded bore of the heat dissipation device to set a minimum spaced distance between a portion of the circuit card and a portion of the heat dissipation device, wherein the threaded spacing element provides a stop defining the minimum spaced distance with a surface of the threaded spacing element abutting the first major surface of the circuit card; and
a locking element threadedly coupled to the threaded spacing element, wherein a surface of the locking element abuts the second major surface of the circuit card to lock the minimum spaced distance.

9. The circuit card apparatus of claim 8, wherein the threaded spacing element comprises a threaded bore and the locking element comprises a threaded member threadably inserted into the threaded bore.

10. The circuit card apparatus of claim 8, wherein the locking element comprises a threaded bore and the threaded spacing element comprises a threaded member threadably inserted into the threaded bore.

11. The circuit card apparatus of claim 8, wherein the thermal interface includes a reflowed thermal interface material.

12. A method of manufacturing a circuit card apparatus comprising the steps of:
(I) pressing a thermal contact surface of a heat dissipation device against a thermal contact surface of a circuit card at a thermal interface, wherein a spaced distance is defined between a portion of the heat dissipation device and a portion of the circuit card;
(II) adjusting a spacing element to set the spaced distance as a minimum spaced distance between the portion of the heat dissipation device and the portion of the circuit card; and
(III) locking the minimum spaced distance.

13. The method of claim 12, wherein step (I) includes melting a thermal interface material at the thermal interface to thermally couple the thermal contact surface of the heat dissipation device with the thermal contact surface of the circuit card.

14. The method of claim 13, further comprising the step of solidifying the melted interface material prior to step (II).

15. The method of claim 12, wherein step (III) includes threadably coupling a locking element to the spacing element.

16. The method of claim 12, step (I) provides the thermal interface with a pressure that is within a range of from about 34.5 kPa (5 psi) to about 416.7 kPa (60 psi).

17. The method of claim 12, wherein step (II) includes adjusting the spacing element until a surface of the spacing element abuts a first surface of one of the circuit card and the heat dissipation device to provide a stop defining the minimum spaced distance.

18. The method of claim 12, wherein step (II) includes threading the spacing element through a threaded bore of one of the circuit card and the heat dissipation device.

19. The method of claim 18, wherein step (II) includes adjusting the spacing element until a surface of the spacing element abuts a first surface of the other of the circuit card and the heat dissipation device to provide a stop defining the minimum spaced distance.

20. The method of claim 12, wherein step (II) includes threadably adjusting the spacing element through a threaded bore of the heat dissipation device until a surface of the spacing element abuts a first surface of the circuit card to provide a stop defining the minimum spaced distance, and step (III) includes threadably coupling a locking element to the spacing element such that a surface of the locking element abuts a second surface of the circuit card.
